(19) United States
(12) Patent Application Publication
(10) Pub. No.: US 2006/0292828 A1
(43) Pub. Date: Dec. 28, 2006

(54) Wafer and method of cutting the same

(75) Inventor: Chien-Yu Chen, Kaohsiung (TW)

Correspondence Address: BACON & THOMAS, PLLC, 625 SLATERS LANE, FOURTH FLOOR, ALEXANDRIA, VA, 22314, US

(73) Assignee: Advanced Semiconductor Engineering, Inc., Kaohsiung (TW)

(21) Appl. No.: 11/293,086

(22) Filed: Dec. 5, 2005

(30) Foreign Application Priority Data
Jun. 22, 2005 (TW) 94120834

(51) Int. Cl. H01L 21/00

(52) U.S. Cl. 438/460

(57) ABSTRACT

A method of cutting a wafer. First, the first substrate and the second substrate are provided. Next, several alignment marks are formed on the backside of the second substrate to form two reference coordinate axes. Then, the first substrate and the second substrate are assembled to form a wafer. The topside of the second substrate faces the lower surface of the first substrate for assembly. Afterwards, the first substrate is cut for forming several first cutting marks. Then, the second substrate is cut according to the two reference coordinate axes, for forming several second cutting marks corresponding to the first cutting marks.

This application claims the benefit of Taiwan application Serial No. 94120834, filed Jun. 22, 2005, the subject matter of which is incorporated herein by reference.

### BACKGROUND OF THE INVENTION

1. Field of the Invention

The invention relates in general to a wafer and a method of cutting the same, and more particularly to a wafer with alignment marks and a method of cutting the same.

2. Description of the Related Art

Referring to FIG. 1, a cross-sectional view of a conventional wafer is shown. The conventional wafer 100 includes a MEMS (Micro Electronic Mechanic System) 120 and a CMOS (Complementary Metal-Oxide Semiconductor) 104. The MEMS 102 is a glass substrate having an upper surface 102a and a lower surface 102b. The CMOS 104 is a silicon substrate having a topside 104a and a backside 104b. A gap 106 separates the lower surface 102b of the MEMS and the topside 104a of the CMOS 104. The adhesive 112 partly fills the gap so as to assemble the MEMS 102 and the CMOS 104.

The conventional cutting method of wafer 100 is firstly to form several first cutting marks 122 on the topside 102a of the MEMS 102, and then to form several second cutting marks 124 on the backside 104b of the CMOS 104. After cutting the wafer 100, force is applied on the first cutting mark 122 and the second cutting mark 124 respectively for separating wafer to several dies.

Referring to FIGS. 2A˜2B, FIG. 2A is a top view of the wafer in FIG. 1 and FIG. 2B is a schematic view showing the backside of the wafer in FIG. 1. The topside 102 of the MEMS firstly faces the cutting device for assembly before the first cutting mark 122 is formed. Because the topside 102 has patterns on its surface, the cutting device could read the patterns by a sensor such as an electric eye and then easily locate and cut the first cutting mark 122. However, there are no patterns on the backside 104b of the CMOS 104, so the cutting device could not read the backside 104b to locate and to cut the second cutting mark 124. Therefore, while forming the first cutting mark 122, the two sides of the MEMS 102 and the COMS 104 should be cut off as a whole for forming the horizontal coordinate axis REF1 and vertical coordinate axis REF2. Both of them would be referred when forming the position of second cutting mark 124. When cutting the second cutting mark 124, the backside 104b of the COMS 104 faces the cutting device even though the backside 104b has no pattern, the cutting mark 124 could be successfully located by cutting device according to the horizontal coordinate axis REF1 and the vertical coordinate axis REF2.

Nevertheless, the materials of MEMS 102 and of CMOS 104 are different; thus it causes many problems when cutting MEMS 102 and CMOS 104 for forming the first coordinate axis REF1 and the second coordinate axis REF2. For example, if the cutter for cutting glass is used to cut the MEMS 102 and the CMOS 104, the CMOS 104 will be curved because of the vibration of the cutter and form flaws on wafer 100. If the cutter for cutting glass and the cutter for cutting silicon are used respectively to cut MEMS 102 and CMOS 104, the inaccuracy is occurred when changing the cutters. The quality of wafers will be influenced due to the dissimilar thickness of different cutters. Moreover, the process of cutting the first coordinate axis REF1 and the second coordinate axis REF2 wastes time and the cutters are damaged with ease; therefore the producing time and cost of the wafer 100 are dramatically raised.

### SUMMARY OF THE INVENTION

It is therefore an object of the invention to provide a wafer and a method of cutting the same. A wafer includes a first substrate and a second substrate having several alignment marks. Two reference coordinate axes formed by alignment marks would be referred while forming the position of the second cutting mark on the backside. The reference coordinate axes formed by alignment marks replace the conventional reference coordinates formed by cutting the first substrate and the second substrate as a whole. Therefore, a wafer and a method of cutting the same of present invention simplify the process and shorten the time of cutting a wafer, also diminish the damage of a cutter.

The invention achieves the above-identified object by providing a method of cutting a wafer. First, the first substrate and the second substrate are provided. Next, several alignment marks are formed on the backside of the second substrate to form two reference coordinate axes. Then, the first substrate and the second substrate are assembled to form a wafer. The topside of the second substrate faces the lower surface of the first substrate for assembly. Afterwards, the first substrate is cut for forming several first cutting marks. Then, the second substrate is cut according to the two reference coordinates, for forming several second cutting marks corresponding to the first cutting marks.

The invention achieves the above-identified object by further providing a wafer including the first substrate, the second substrate and an adhesive. The first substrate has lower surface and the second substrate has a topside and a backside. The topside faces the lower surface for assembly and the backside has several alignment marks to form two reference coordinate axes. The adhesive is filled between the lower surface and the topside so as to assemble the first and the second substrate.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1 (Prior Art) is a cross-sectional view showing a conventional wafer.

FIG. 2A (Prior Art) is a top view of the wafer in FIG. 1.

FIG. 2B (Prior Art) is a schematic view showing the backside of the wafer in FIG. 1.

FIG. 3 is a flowchart of a cutting method of the wafer according to a preferred embodiment of the invention.

FIGS. 4A˜4E illustrate the cutting method of the wafer in FIG. 3.

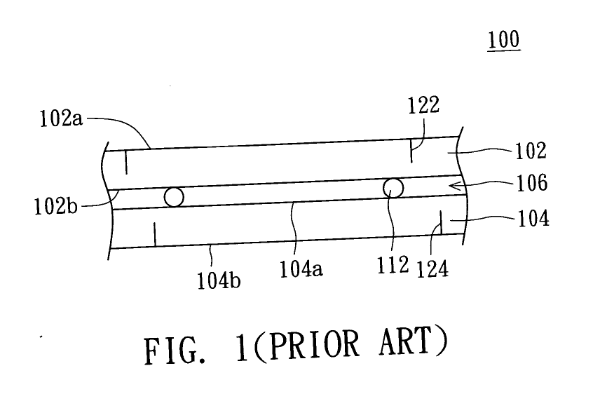

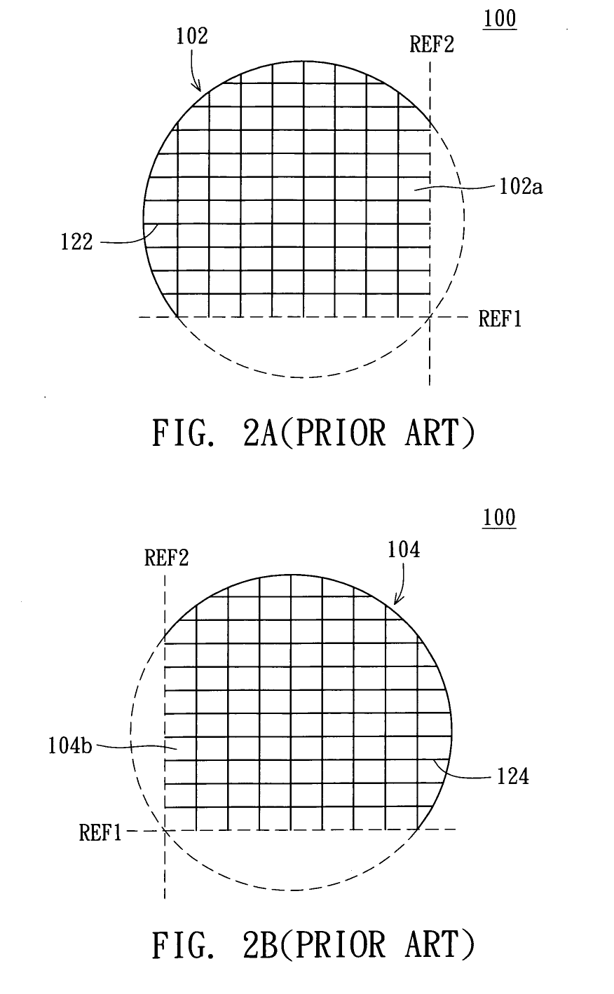

### DETAILED DESCRIPTION OF THE INVENTION

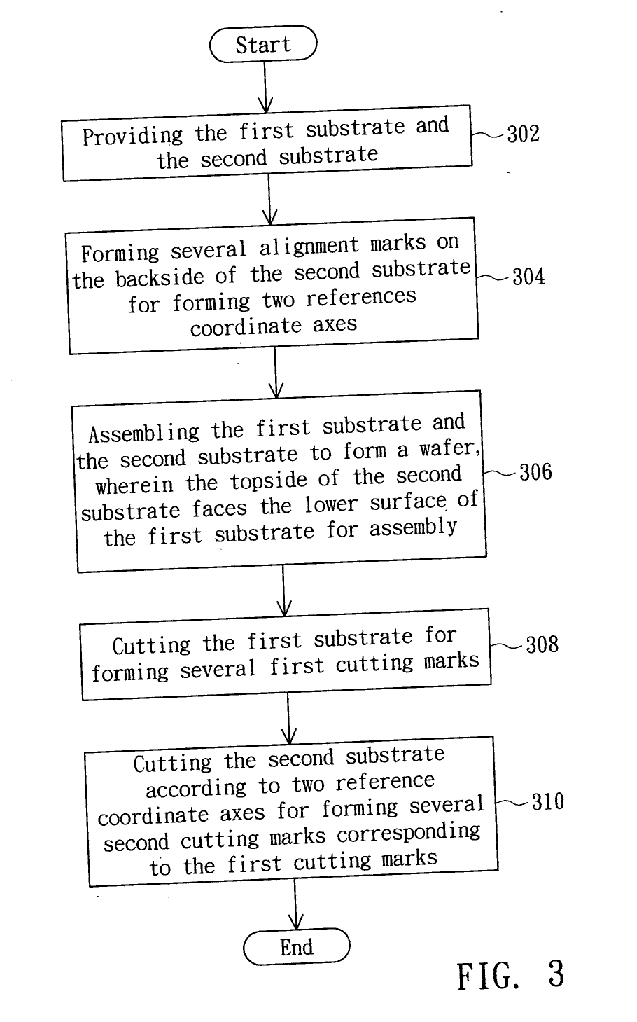

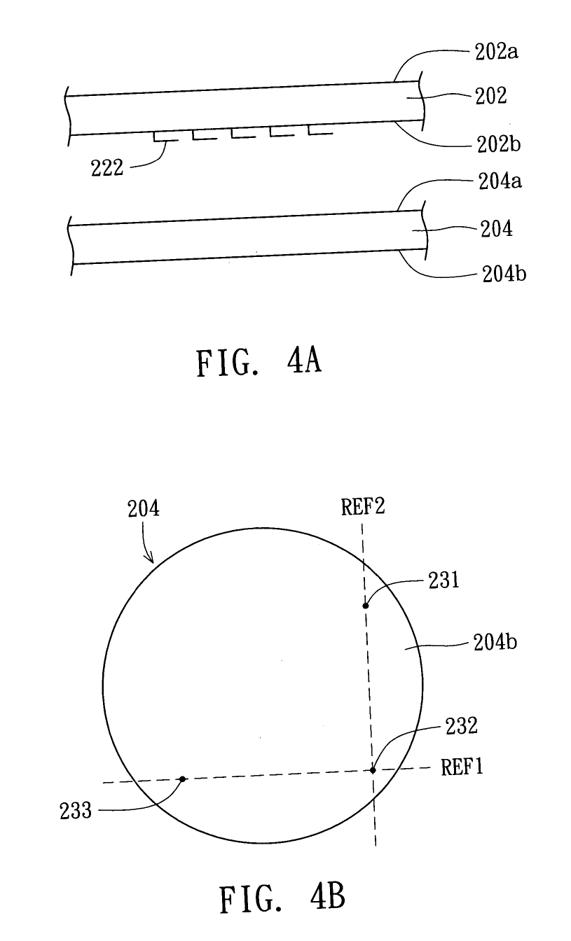

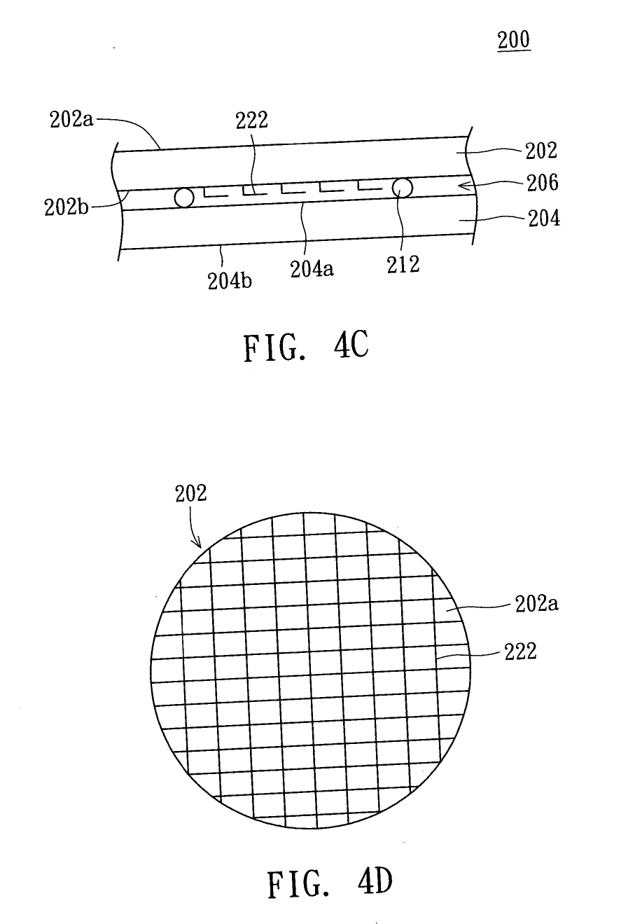

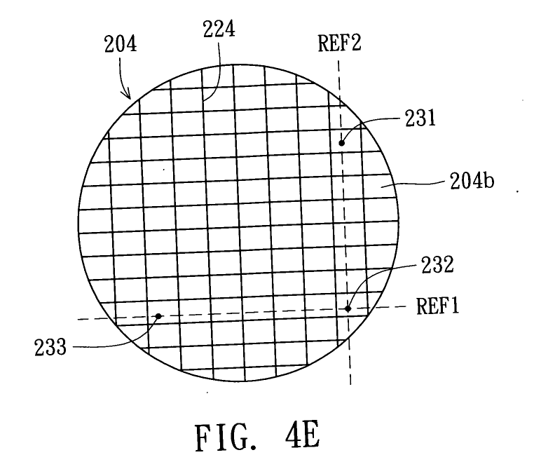

Referring to FIG. 3, a flowchart of the cutting method of the wafer is shown according to an embodiment of the invention. FIGS. 4A˜4E illustrate the cutting method of the wafer in FIG. 3. The cutting method of the wafer of the embodiment includes steps 302˜310.

First, as shown in step 302 and FIG. 4A, the first substrate 202 and the second substrate 204 are provided. The first substrate 202 such as the MEMS (Micro Electronic Mechanic System) 202 has upper surface 202a and lower surface 202b. The first substrate 202 such as a glass substrate preferably includes several cantilevers 222. The cantilevers 222 made of, for instance, aluminum, are formed on the lower surface 202b of the first substrate 202. The second substrate 204 such as the CMOS having a topside 204a and a backside 204b preferably is a silicon substrate and has for example, several circuit areas on the topside 204a corresponding to cantilevers 222.

Afterwards, as shown in step 304 and FIG. 4B, some alignment marks are formed on the backside 204b of the second substrate 204 to form two reference coordinate axes. In this preferred embodiment, an example of forming three alignment marks is used for illustration. As shown in FIG. 4B, the first alignment mark, the second alignment mark and the third alignment mark formed on the backside of 204b form a horizontal coordinate axis REF1 and vertical coordinate axis REF2. The first alignment mark 231, the second alignment mark 232 and the third alignment mark 233 are, for example, several holes and are preferably formed by an etching technique. However, it is to be appreciated by person having ordinary skill in the art that the amount of alignment marks and coordinate axes of the present invention are not limited and several alignment marks and coordinate axes also could be formed on the backside depending on practical application for appropriate variation.

Then as shown in step 306 and FIG. 4C, the first substrate 202 and the second substrate 204 are assembled to form the wafer 200. The topside 204a of the second substrate 204 faces the lower surface 202b of the first substrate 202 for assembly. For instance, there is a gap between the first substrate 202 and the second substrate 204, and the adhesive 212 partly fills the gap 206 so as to assemble the first substrate 202 and the second substrate 204. In the adhesive 212, for example, there are several spacers such as glass balls uniformly disposed to steady the value of gap 206 between the first substrate 202 and the second substrate 204 and the gap 206 also contains the cantilever 222.

Moreover, as shown in step 308 and FIG. 4D, the first substrate 202 is cut to form several first cutting marks. For instance, the first cutter is used to cut the first substrate 202 and washed by a liquid, such as DI water (Deionized Water), to cold down the first cutter. There are patterns on the topside surface 202a of the first substrate 202. The cutting device could read the patterns by a sensor such as an electric eye and then easily locate and cut the first cutting mark 222.

Afterwards, as shown in step 310 and FIG. 4E, the second substrate 204 is cut according to two reference coordinate axes to form several second cutting marks 224 corresponding to the first cutting mark. For example, the second cutter is used to cut the second substrate 204 and the second cutter is washed by a liquid such as DI water (Deionized Water) to cool down the second cutter. The two reference coordinate axes are, for example, a horizontal coordinate axis REF1 and a vertical coordinate axis REF2 formed according to the first alignment mark 231, the second alignment mark 232 and the third alignment mark 233.

The wafer and the method of cutting the same in present embodiment is to form several alignment marks on the backside of the second substrate for forming two reference coordinate axes which replaces the coordinates conventionally formed by cutting the first substrate and the second substrate as a whole. The problem that the second substrate is easily damaged or inaccurately positioned when the first substrate and the second substrate are cut conventionally to form reference coordinate axes could be avoided. Moreover, the wafer and the method of cutting the same in present embodiment could diminish the damage of the cutter, reduce the cost of cutting wafers, and also substantially shorten the time of cutting wafers.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A method of cutting a wafer, comprising:
providing a first substrate and a second substrate;
forming a plurality of alignment marks on a backside of the second substrate to form two reference coordinate axes; and
assembling the first substrate and the second substrate to form a wafer, wherein a topside of the second substrate faces the lower surface of the first substrate for assembly;
cutting the first substrate to form a plurality of first cutting marks; and
cutting the second substrate according to the two reference coordinate axes for forming a plurality of second cutting marks corresponding to the first cutting marks.

2. The method according to claim 1, wherein the first substrate and the second substrate are respectively cut by a first cutter and a second cutter.

3. The method according to claim 2, wherein the first cutter and the second cutter are washed by a liquid for cooling the first cutter and the second cutter.

4. The method according to claim 3, wherein the liquid is DI Water (Deionized Water).

5. The method according to claim 1, wherein the plurality of alignment marks include a first alignment mark, a second alignment mark and a third alignment mark.

6. The method according to claim 1, wherein the two reference coordinate axes comprise a horizontal coordinate axis and a vertical coordinate axis.

7. The method according to claim 1, wherein the alignment marks are formed by an etching technique.

8. The method according to claim 1, wherein the alignment marks are a plurality of holes.

9. The method according to claim 1, wherein the first substrate further comprises a plurality of cantilevers and the cantilevers are formed on the lower surface.

10. The method according to claim 9, wherein the cantilevers are made of aluminum.

11. The method according to claim 10, wherein the topside of the second substrate has a plurality of circuit areas.

12. The method according to claim 11, wherein the circuit areas are corresponding to the positions of cantilevers.

13. The method according to claim 1, wherein the first substrate is a glass substrate and the second substrate is a silicon substrate.
